(19) United States
(12) Patent Application Publication
(10) Pub. No.: US 2026/0043715 A1
(43) Pub. Date: Feb. 12, 2026

(54) METHOD AND APPARATUS FOR EVALUATING HEALTH STATE OF SINTERING DEVICE

(71) Applicants: Zhuzhou Ruideer Intelligent Equipment Co., Ltd., Zhuzhou (CN); Hunan Linxin New Materials Co., Ltd., Changsha (CN)

(72) Inventors: Kejian CHEN, Zhuzhou (CN); Peiyu WANG, Zhuzhou (CN); Xingyu WANG, Zhuzhou (CN); Simin ZOU, Zhuzhou (CN); Yingxin LI, Zhuzhou (CN)

(73) Assignees: Zhuzhou Ruideer Intelligent Equipment Co., Ltd., Zhuzhou (CN); Hunan Linxin New Materials Co., Ltd., Changsha (CN)

(21) Appl. No.: 18/685,868

(22) PCT Filed: Sep. 1, 2021
(86) PCT No.: PCT/CN2021/115961

§ 371 Date: Feb. 22, 2024

(30) Foreign Application Priority Data
Aug. 23, 2021 (CN) 202110965517.4

(51) Int. Cl. G01M 99/00

(52) U.S. Cl. CPC G01M 99/00

(57) ABSTRACT

Disclosed in the present disclosure are a method and apparatus for evaluating a health state of a sintering device. The method includes: acquiring state information of a sintering device, where the state information of the sintering device includes at least one state parameter of the sintering device; and determining a health state of the sintering device according to the state information of the sintering device and a preset health state evaluation rule, where the health state of the sintering device is used for indicating intelligent operation and maintenance for the sintering device. It can be seen that by means of the present disclosure, state information of a sintering device is acquired, and then a health state of the sintering device for indicating intelligent operation and maintenance for the sintering device can be determined by using a health state evaluation rule.

### CROSS-REFERENCE TO RELATED APPLICATION

This patent application is a national stage application of International Patent Application No. PCT/CN2021/115961, filed on Sep. 1, 2021, which claims the benefit and priority of Chinese Patent Application No. 202110965517.4, filed with the China National Intellectual Property Administration on Aug. 23, 2021, the disclosure of which is incorporated by reference herein in its entirety as part of the present application.

### TECHNICAL FIELD

The present disclosure relates to the field of health evaluation of devices, and in particular to a method and apparatus for evaluating a health state of a sintering device.

### BACKGROUND

At present, device health management technology has been paid more and more attention. Especially in the key monitoring data of sintering devices, the data closely related to the health state of device include temperature data and vibration data. Based on the operation data of the sintering device, statistical analysis is often used to evaluate the health of the sintering device. Although this method is easy to implement, it has strong limitations and relies too much on manual experience, the accuracy of the evaluation results has a great correlation with the professional experience of appraisers, and it is difficult to achieve rapid and accurate evaluation of the health state of the sintering device. Therefore, it is particularly important to provide a method and apparatus for evaluating a health state of a sintering device, so as to achieve rapid and accurate evaluation of the health state of the sintering device, and improve the capability of fault prediction and intelligent operation and maintenance for the sintering device.

### SUMMARY

A technical problem to be solved by the present disclosure is to provide a method and apparatus for evaluating a health state of a sintering device. By means of the present disclosure, state information of a sintering device is acquired, and then a health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device.

In order to solve the technical problem above, a method for evaluating a health state of a sintering device is disclosed in a first aspect of the embodiment of the present disclosure, including the following steps:
acquiring state information of a sintering device, where the state information of the sintering device includes at least one state parameter of the sintering device; and
determining a health state of the sintering device according to the state information of the sintering device and a preset health state evaluation rule, where the health state of the sintering device is used for indicating intelligent operation and maintenance for the sintering device.

As an alternative embodiment, in the first aspect of the embodiment of the present disclosure, determining a health state of the sintering device according to the state information of the sintering device and a preset health state evaluation rule includes the following steps:
determining a parameter health state set according to the state information of the sintering device, where the parameter health state set includes a deviation value corresponding to at least one state parameter of the sintering device; and
determining the health state of the sintering device according to the parameter health state set.

As an alternative embodiment, in the first aspect of the embodiment of the present disclosure, determining a parameter health state set according to the state information of the sintering device includes the following steps:
for any state parameter of the sintering device, determining a deviation value corresponding to the state parameter of the sintering device according to the state parameter of the sintering device and a preset reference value corresponding to the state parameter of the sintering device.

As an alternative embodiment, in the first aspect of the embodiments of the present disclosure, determining a health state of the sintering device according to the parameter health state set includes the following steps:
determining a device parameter state type according to the parameter health state set;
determining whether the device parameter state type is matched with a fault type to obtain a first matching result;
when the first matching result indicates that the device parameter state type is matched with the fault type, determining the health state of the sintering device according to the device parameter state type;
when the first matching result indicates that the device parameter state type is mismatched with the fault type, determining a parameter deviation set according to the state information of the sintering device, where the parameter deviation set includes a deviation change rate corresponding to at least one state parameter of the sintering device; and
determining the health state of the sintering device according to the parameter health state set and the parameter deviation set.

As an alternative embodiment, in the first aspect of the embodiments of the present disclosure, the device parameter state type includes a device parameter fault type, and/or a device parameter health type.

Determining the device parameter state type according to the parameter health state set includes the following steps:
determining a parameter state type set according to the parameter health state set, where the parameter state type set includes a parameter state type corresponding to at least one state parameter of the sintering device;
matching all parameter state types in the parameter state type set with the parameter fault type to obtain a second matching result;
when the second matching result indicates that a target parameter state type matched with the parameter fault type exists in the parameter state type set, determining the device parameter state type as the device parameter fault type; and
when the second matching result indicates that no target parameter state type matched with the parameter fault type exists in the parameter state type set, determining the device parameter state type as the device parameter health type.

As an alternative embodiment, in the first aspect of the embodiments of the present disclosure, determining a health state of the sintering device according to the parameter health state set and the parameter deviation set includes the following steps:
determining a parameter health value set according to the parameter health state set and the parameter deviation set, where the parameter health value set includes a parameter health value corresponding to at least one state parameter of the sintering device; and
determining the health state of the sintering device according to the parameter health value set and a preset weighted evaluation rule.

As an alternative embodiment, in the first aspect of the embodiment of the present disclosure, acquiring state information of the sintering device includes the following steps:
acquiring initial state parameter information, where the initial state parameter information includes at least one initial state parameter; and
determining state information of the sintering device according to the initial state parameter information.

As an alternative embodiment, in the first aspect of the embodiment of the present disclosure, determining state information of the sintering device according to the initial state parameter information includes the following steps:
determining an initial state parameter type set according to the initial state parameter information, where the initial state parameter type set includes a parameter type corresponding to at least one initial state parameter;
for any initial state parameter, determining whether the parameter type corresponding to the initial state parameter satisfies a processing condition or not, so as to obtain a first determination result; and
when the first determination result indicates that the parameter type corresponding to the initial state parameter satisfies the processing condition, obtaining a state parameter of the sintering device corresponding to the initial state parameter according to the initial state parameter and a preset data processing rule.

According to a second aspect of the embodiment of the present disclosure, an apparatus for evaluating a health state of a sintering device is disclosed, including:
an acquisition module, configured to acquire state information of a sintering device, where the state information of the sintering device includes at least one state parameter of the sintering device; and
a determination module, configured to determine a health state of the sintering device according to the state information of the sintering device and a preset health state evaluation rule, where the health state of the sintering device is used for indicating intelligent operation and maintenance for the sintering device.

As an alternative embodiment, in the second aspect of the embodiment of the present disclosure, the determination module includes a first determination submodule and a second determination submodule.

The first determination submodule is configured to determine a parameter health state set according to the state information of the sintering device, where the parameter health state set includes a deviation value corresponding to at least one state parameter of the sintering device.

The second determination submodule is configured to determine the health state of the sintering device according to the parameter health state set.

As an alternative embodiment, in the second aspect of the embodiment of the present disclosure, a specific mode for the first determination submodule to determine the parameter health state set according to the state information of the sintering device is as follows:
for any state parameter of the sintering device, determining a deviation value corresponding to the state parameter of the sintering device according to the state parameter of the sintering device and a preset reference value corresponding to the state parameter of the sintering device.

As an alternative embodiment, in the second aspect of the embodiment of the present disclosure, a specific mode for the second determination submodule to determine a health state of the sintering device according to the parameter health state set is as follows:
determining a device parameter state type according to the parameter health state set;
determining whether the device parameter state type is matched with a fault type or not, so as to obtain a first matching result;
when the first matching result indicates that the device parameter state type is matched with the fault type, determining the health state of the sintering device according to the device parameter state type;
when the first matching result indicates that the device parameter state type is mismatched with the fault type, determining a parameter deviation set according to the state information of the sintering device, where the parameter deviation set includes a deviation change rate corresponding to at least one state parameter of the sintering device; and
determining the health state of the sintering device according to the parameter health state set and the parameter deviation set.

As an alternative embodiment, in the second aspect of the embodiment of the present disclosure, the device parameter state type includes a device parameter fault type, and/or a device parameter health type.

A specific mode for the second determination submodule to determine the device parameter state type according to the parameter health state set is as follows:
determining a parameter state type set according to the parameter health state set, where the parameter state type set includes a parameter state type corresponding to at least one state parameter of the sintering device;
matching all parameter state types in the parameter state type set with the parameter fault type to obtain a second matching result;
when the second matching result indicates that there is a target parameter state type matched with the parameter fault type in the parameter state type set, determining the device parameter state type as the device parameter fault type; and
when the second matching result indicates that there is no target parameter state type matched with the parameter fault type in the parameter state type set, determining the device parameter state type as the device parameter health type.

As an alternative embodiment, in the second aspect of the embodiment of the present disclosure, a specific mode for the second determination submodule to determine the health state of the sintering device according to the parameter health state set and the parameter deviation set is as follows:
determining a parameter health value set according to the parameter health state set and the parameter deviation set, where the parameter health value set includes a parameter health value corresponding to at least one state parameter of the sintering device; and
determining the health state of the sintering device according to the parameter health value set and a preset weighted evaluation rule.

As an alternative embodiment, in the second aspect of the embodiments of the present disclosure, the acquisition module includes an acquisition submodule and a third determination submodule.

The acquisition submodule is configured to acquire initial state parameter information, where the initial state parameter information includes at least one initial state parameter.

The third determination submodule is used to determine the state information of the sintering device according to the initial state parameter information.

As an alternative embodiment, in the second aspect of the embodiment of the present disclosure, a specific mode for the third determination submodule to determine the state information of the sintering device according to the initial state parameter information is as follows:
determining an initial state parameter type set according to the initial state parameter information, where the initial state parameter type set includes a parameter type corresponding to at least one initial state parameter;
for any initial state parameter, determining whether a parameter type corresponding to the initial state parameter satisfies a processing condition or not, so as to obtain a first determination result; and
when the first determination result indicates that the parameter type corresponding to the initial state parameter satisfies the processing condition, obtaining a state parameter of the sintering device corresponding to the initial state parameter according to the initial state parameter and a preset data processing rule.

According to a third aspect of the embodiment of the present disclosure, another apparatus for evaluating a health state of a sintering device includes:
a memory, in which executable program codes are stored; and
a processor coupled to the memory.

The processor calls the executable program codes stored in the memory to execute a part or all of steps in the method for evaluating a health state of a sintering device disclosed in the first aspect of the embodiment of the present disclosure.

In a fourth aspect of the present disclosure, a computer storage medium is provided, which is used to store computer instructions. When the computer instructions are called, the computer storage medium is used for executing part or all of steps in the method for evaluating a health state of a sintering device disclosed in the first aspect of the embodiment of the present disclosure.

Compared with the prior art, the present disclosure has the following beneficial effects:

In the embodiments of the present disclosure, the method includes the steps: acquiring state information of a sintering device, where the state information of the sintering device includes at least one state parameter of the sintering device; and determining a health state of the sintering device according to the state information of the sintering device and a preset health state evaluation rule, where the health state of the sintering device is used for indicating intelligent operation and maintenance for the sintering device. It can be seen that by means of the present disclosure, state information of a sintering device is acquired, and then a health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device.

### BRIEF DESCRIPTION OF THE DRAWINGS

To describe the technical solutions of the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a flow diagram of a method for evaluating a health state of a sintering device according to embodiments of the present disclosure;

FIG. 2 is a flow diagram of another method for evaluating a health state of a sintering device according to embodiments of the present disclosure;

FIG. 3 is a structural diagram of an apparatus for evaluating a health state of a sintering device according to embodiments of the present disclosure;

FIG. 4 is a structural diagram of another apparatus for evaluating a health state of a sintering device according to embodiments of the present disclosure;

FIG. 5 is a structural diagram of still another apparatus for evaluating a health state of a sintering device according to embodiments of the present disclosure.

### DETAILED DESCRIPTION OF THE EMBODIMENTS

In order to make those skilled in the art understand the technical solutions of the present disclosure better, the following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

The terms “first” and “second” in the description and claims of the present disclosure and the above drawings are used to distinguish different objects, rather than describing a specific order. Furthermore, that terms “including” and “have” and any variations thereof are intended to cover non-exclusive inclusion. For example, a process, method, apparatus, product, or device including a series of steps or units is not limited to the listed steps or units, it can optionally include other steps or units that are not listed; alternatively, other steps or units inherent to the process, method, product, or device can be included either.

The term “embodiment” referred to herein means that a particular feature, structure, or feature described in conjunction with the embodiment may be contained in at least one embodiment of the present disclosure. The phrase appearing in various places in the specification does not necessarily refer to the same embodiment, nor does it refer to an independent or alternative embodiment that is mutually exclusive with other embodiments. It is expressly and implicitly understood by those skilled in the art that an embodiment described herein may be combined with other embodiments.

By means of a method and apparatus for evaluating a health state of a sintering device of the present disclosure, state information of a sintering device is acquired, and then a health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device. The method and apparatus are described in detail below, respectively.

### Embodiment 1

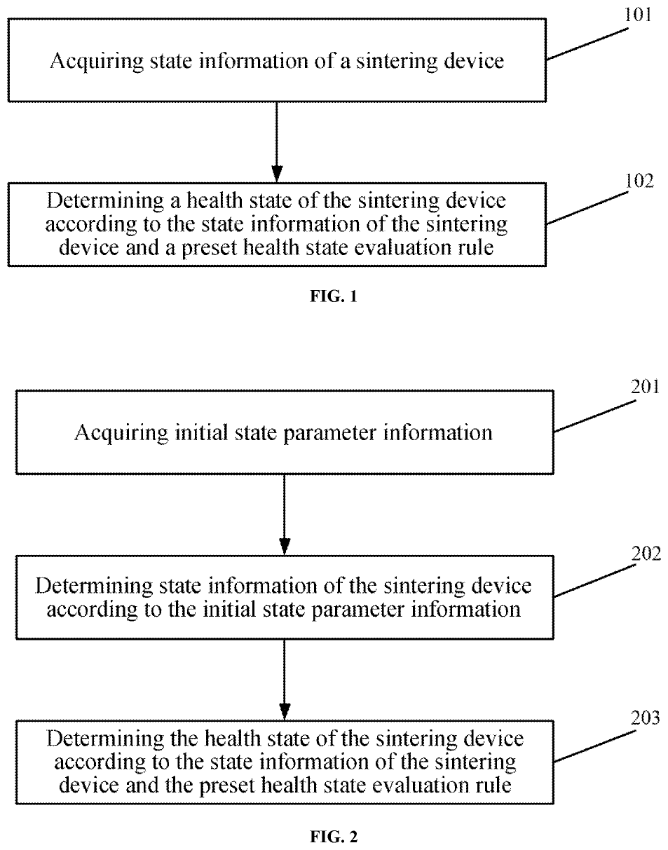

Please referring to FIG. 1, FIG. 1 is a flow diagram of a method for evaluating a health state of a sintering device according to embodiments of the present disclosure. The method for evaluating a health state of a sintering device described in FIG. 1 is applied to a device health system, such as a local server or cloud server for evaluating and managing the health state of the sintering device, which is not limited in the embodiment of the present disclosure. As shown in FIG. 1, the method for evaluating a health state of a sintering device may include the following steps:

101. State information of the sintering device is acquired.

In the embodiment of the present disclosure, the state information of the sintering device includes at least state parameter of the sintering device.

102. A health state of the sintering device is determined according to the state information of the sintering device and a preset health state evaluation rule.

In the embodiment of the present disclosure, the health state of the sintering device is used for indicating intelligent operation and maintenance for the sintering device.

In the embodiment of the present disclosure, the state parameter of the sintering device includes a flow rate, and/or a current, and/or pressure; and/or a voltage, and/or a temperature, which is not limited in the embodiment of the present disclosure.

It can be seen that by implementing a method for evaluating a health state of a sintering device described by the embodiment of the present disclosure, the state information of the sintering device can be acquired, and then the health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device.

In an alternative embodiment, determining a health state of the sintering device according to the state information of the sintering device and a preset health state evaluation rule in Step 102 includes the following steps:
determining a parameter health state set according to the state information of the sintering device, where the parameter health state set includes a deviation value corresponding to at least one state parameter of the sintering device; and
determining the health state of the sintering device according to the parameter health state set.

In the embodiment of the present disclosure, after acquiring all state parameters of the sintering device for evaluating the health state of the sintering device, the state parameters of the sintering device are processed to obtain deviation values corresponding to various state parameters of the sintering device, and then the health state of the sintering device is determined according to the deviation values.

It can be seen that by implementing a method for evaluating a health state of a sintering device described by the embodiment of the present disclosure, the parameter health state set including the deviation value corresponding to the state parameter of the sintering device can be determined according to the state information of the sintering device, and the health state of the sintering device can be determined. An implementation path for determining the health state of the sintering device is provided, such that the rapid and accurate evaluation of the health state of the sintering device is facilitated, thereby improving the capability of fault prediction and intelligent operation and maintenance for the sintering device.

In another alternative embodiment, determining the parameter health state set according to the state information of the sintering device includes the following steps:
for any state parameter of the sintering device, determining a deviation value corresponding to the state parameter of the sintering device according to the state parameter of the sintering device and a preset reference value corresponding to the state parameter of the sintering device.

In the embodiment of the present disclosure, for any state parameter x of the sintering device, there is a reference value rₓ corresponding to the state parameter x of the sintering device in a database, and a deviation value eₓ corresponding to the state parameter of the sintering device can be represented as follows:

$${e}_{x} = x - {r}_{x} .$$

It can be seen that by implementing a method for evaluating a health state of a sintering device described by the embodiment of the present disclosure, the deviation value corresponding to the state parameter of the sintering device can be determined according to the state parameter of the sintering device and the reference value corresponding to the state parameter of the sintering device, such that the rapid and accurate evaluation of the health state of the sintering device is facilitated, thereby improving the capability of fault prediction and intelligent operation and maintenance for the sintering device.

In still another embodiment, determining the health state of the sintering device according to the parameter health state set includes the following steps:
determining a device parameter state type according to the parameter health state set;
determining whether the device parameter state type is matched with a fault type or not, so as to obtain a first matching result;
when the first matching result indicates that the device parameter state type is matched with the fault type, determining the health state of the sintering device according to the device parameter state type;
when the first matching result indicates that the device parameter state type is mismatched with the fault type, determining a parameter deviation set according to the state information of the sintering device, where the parameter deviation set includes a deviation change rate corresponding to at least one state parameter of the sintering device; and
determining the health state of the sintering device according to the parameter health state set and the parameter deviation set.

In an embodiment of the present disclosure, a device parameter state type is determined according to the deviation value corresponding to the state parameter of the sintering device.

In the embodiment of the present disclosure, when the device parameter state type is the device parameter fault type, the first matching result indicates that the device parameter state type is matched with the fault type, the health state of the sintering device is determined as a fault state.

When the first matching result indicates that the device parameter state type is mismatched with the fault type, the parameter deviation set is determined according to the state information of the sintering device. Specifically, for any state parameter x of the sintering device, the corresponding deviation value eₓ thereof is subjected to integral transformation in time to obtain a deviation change rate ecₓ, which can be represented as follows:

$$e {c}_{x} = d {r}_{x} / dt .$$

It can be seen that by implementing a method for evaluating a health state of a sintering device described by the embodiment of the present disclosure, the health state of the sintering device can be determined by determining the device parameter state type, then the parameter deviation set including a deviation change rate corresponding to the state parameter of the sintering device is determined according to the state information of the sintering device, and then the health state of the sintering device is determined according to the parameter health state set and the parameter deviation set, such that the rapid and accurate evaluation of the health state of the sintering device is facilitated, thereby improving the capability of fault prediction and intelligent operation and maintenance for the sintering device.

In still another alternative embodiment, the device parameter state type includes a device parameter fault type, and/or a device parameter health type.

Determining the device parameter state type according to the parameter health state set includes the following steps:
determining a parameter state type set according to the parameter health state set, where the parameter state type set includes a parameter state type corresponding to at least one state parameter of the sintering device;
matching all parameter state types in the parameter state type set with the parameter fault type to obtain a second matching result;
when the second matching result indicates that there is a target parameter state type matched with the parameter fault type in the parameter state type set, determining the device parameter state type as the device parameter fault type; and
when the second matching result indicates that there is no target parameter state type matched with the parameter fault type in the parameter state type set, determining the device parameter state type as the device parameter health type.

In the embodiment of the present disclosure, the parameter state type set is determined according to the parameter health state set. Specifically, for the deviation value eₓ corresponding to any state parameter of the sintering device, there is a state threshold sₓ corresponding to the state parameter x of the sintering device in a database, and a state value eeₓ corresponding to the state parameter of the sintering device is calculated, which may be represented as follows:

$${ee}_{x} = \vert {e}_{x} \vert / {r}_{x} .$$

Further, the state value eeₓ corresponding to the state parameter of the sintering device is compared with the state threshold sₓ corresponding to the state parameter of the sintering device for determination, when the state value eeₓ corresponding to the state parameter of the sintering device is greater than or equal to the state threshold sₓ corresponding to the state parameter of the sintering device, it is determined that the parameter state type corresponding to the state parameter of the sintering device is the parameter fault type. When the state value eeₓ corresponding to the state parameter of the sintering device is less than the state threshold sₓ corresponding to the state parameter of the sintering device, it is determined that the parameter state type corresponding to the state parameter of the sintering device is the parameter health type.

Alternatively, a specific mode for matching all parameter state types in the parameter state type set with the parameter fault type to obtain a second matching result is as follows:
determining whether there is the parameter fault type in all parameter state types in the parameter state type set or not.

When there is the parameter fault type in the parameter state type set, the second matching result indicates that there is a target parameter state type matched with the parameter fault type in the parameter state type set.

When there is no parameter fault type in the parameter state type set, the second matching result indicates that there is no target parameter state type matched with the parameter fault type in the parameter state type set.

It can be seen that by implementing a method for evaluating a health state of a sintering device described by the embodiment of the present disclosure, the parameter state type set can be determined according to the parameter health state set, and then the device parameter state type is determined by matching, such that the rapid and accurate evaluation of the health state of the sintering device is facilitated, thereby improving the capability of fault prediction and intelligent operation and maintenance for the sintering device.

In still another alternative embodiment, determining the health state of the sintering device according to the parameter health state set and the parameter deviation set includes the following steps:
determining a parameter health value set according to the parameter health state set and the parameter deviation set, where the parameter health value set includes a parameter health value corresponding to at least one state parameter of the sintering device; and
determining the health state of the sintering device according to the parameter health value set and a preset weighted evaluation rule.

In the embodiment of the present disclosure, a specific mode for determining the parameter health value set according to the parameter health state set and the parameter deviation set is as follows:
for any state parameter x of the sintering device, a deviation value eₓ corresponding to the state parameter of the sintering device and a deviation change rate ecₓ corresponding to the state parameter of the sintering device are subjected to fuzzification and fuzzy reasoning by using fuzzy membership criterion, so as to obtain a fuzzy health value corresponding to the state parameter of the sintering device, and then the fuzzy health value is subjected to defuzzification to obtain the parameter health value corresponding to the state parameter of the sintering device.

Alternatively, fuzzifying the deviation value eₓ corresponding to the state parameter of the sintering device and the deviation change rate ecₓ corresponding to the state parameter of the sintering device includes performing fuzzy quantization on the deviation value eₓ corresponding to the state parameter of the sintering device and the deviation change rate ecₓ corresponding to the state parameter of the sintering device using relative values. Specifically, after the deviation value eₓ and the deviation change rate ecₓ are converted into a first deviation value eₓᵣ and a first deviation change rate ecₓᵣ, the first deviation value eₓᵣ and a first deviation change rate ecₓᵣ are quantized.

$$Alternatively , {e}_{x r} = {e}_{x} / {r}_{x} . Alternatively , {ec}_{x r} = d ( {e}_{x} / {r}_{x} ) / dt .$$

Alternatively, the first deviation value eₓᵣ and the first deviation change rate ecₓᵣ adopt a fuzzy subset of the same language value.

Alternatively, the fuzzy subset includes negative big, negative middle, negative small, zero, positive small, positive middle, and positive big.

Alternatively, the quantization levels of the first deviation value eₓᵣ and the first deviation change rate ecₓᵣ are N levels. N is a positive integer.

Alternatively, the first deviation value eₓᵣ and the first deviation change rate ecₓᵣ correspond to a first domain and a second domain.

Alternatively, for the first deviation value eₓᵣ and the first deviation change rate ecₓᵣ corresponding to any state parameter x of the sintering device, mapping values of the first deviation value eₓᵣ and the first deviation change rate ecₓᵣ on the first domain and the second domain are mapped to N quantization levels, and then a first membership assignment and a second membership assignment of the first deviation value eₓᵣ and the first deviation change rate ecₓᵣ on fuzzy subset variables are obtained through membership functions.

Alternatively, the membership function is a Gaussian function.

Alternatively, for the first deviation value eₓᵣ and the first deviation change rate ecₓᵣ corresponding to any state parameter x of the sintering device, a fuzzy healthy value Hₓₘ corresponding to the state parameter x of the sintering device can be determined according to the first membership assignment and the second membership assignment and a preset health degree fuzzy rule, and then the current health degree level Hₓᵣ can be determined according to the fuzzy health value Hₓₘ. Further, a parameter health value Hₓ corresponding to the state parameter x of the sintering device is determined according to the current health degree level Hₓᵣ corresponding to the state parameter x of the sintering device and a basic domain Hₓₓ of the health degree corresponding to the state parameter x of the sintering device.

Alternatively, there is a mapping relationship between the basic domain of the health degree and the health degree level.

Alternatively, the health degree level is M. M is a positive integer.

Alternatively, the health degree fuzzy rule includes a fuzzy rule table based on the first membership assignment and the second membership assignment.

In the embodiment of the present disclosure, a specific mode for determining the health state of the sintering device according to the parameter health value set and a preset weighted evaluation rule is as follows:
multiplying the parameter health value corresponding to the state parameter of the sintering device with a weighting coefficient corresponding to the state parameter of the sintering device to obtain a weighted health value corresponding to the state parameter of the sintering device, and then summing all the weighted health values to obtain the health value of the sintering device, and determining the health state of the sintering device according to the health value of the sintering device and a health state rating rule of the sintering device. For example, when the state parameters of the sintering device include temperature, pressure and voltage, their corresponding parameter health values are 70, 80 and 90, and their corresponding weighting coefficients are 0.3, 0.3 and 0.4, so the corresponding weighted health values are calculated to be 21, 24 and 36, respectively, and then the corresponding health value of the sintering device corresponding to the sintering device is calculated to be 81. The health state rating rules of the sintering device are health, in need of maintenance and in need of overhaul, and the corresponding health value ranges of the sintering device are [0,60], [60,80] and [80, 100] respectively, and thus, it can be determined that the health state of the sintering device corresponding to the sintering device is health.

It can be seen that by implementing a method for evaluating a health state of a sintering device described by the embodiment of the present disclosure, the parameter health value set can be determined according to the parameter health state set and the parameter deviation set, and the health state of the sintering device can be determined according to the weighted evaluation rule, such that the rapid and accurate evaluation of the health state of the sintering device is facilitated, thereby improving the capability of fault prediction and intelligent operation and maintenance for the sintering device.

### Embodiment 2

Please referring to FIG. 2, FIG. 2 is a flow diagram of another method for evaluating a health state of a sintering device according to embodiments of the present disclosure. The method for evaluating a health state of a sintering device described in FIG. 2 is applied to a device health system, such as a local server or cloud server for evaluating and managing the health state of the sintering device, which is not limited in the embodiment of the present disclosure. As shown in FIG. 2, the method for evaluating a health state of a sintering device may include the following steps:

201. Initial state parameter information is acquired.

In the embodiment of the present disclosure, the initial state parameter information includes at least one initial state parameter.

202. State information of the sintering device is determined according to the initial state parameter information.

203. A health state of the sintering device is determined according to the state information of the sintering device and a preset health state evaluation rule.

In the embodiment of the present disclosure, the specific technical details and explanation of technical terms of Step 203 can refer to the detailed description of Step 102 in Embodiment 1, which will not be described in detail in the embodiment of the present disclosure.

In the embodiment of the present disclosure, the initial state parameter includes an initial flow rate, and/or an initial current, and/or initial pressure, and/or an initial voltage, and/or an initial temperature, which is not limited in the embodiment of the present disclosure.

Alternatively, the initial state parameter information may be acquired by means of a sensor, or acquired from a device health system, which is not limited in the embodiment of the present disclosure.

It can be seen that by means of a method for evaluating a health state of a sintering device described by the embodiment of the present disclosure, state information of the sintering device can be determined through the initial state parameter information, and then the health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device.

In an alternative embodiment, determining the state information of the sintering device according to the initial state parameter information in Step 202 includes the following steps:
determining an initial state parameter type set according to the initial state parameter information, where the initial state parameter type set includes a parameter type corresponding to at least one initial state parameter;
for any initial state parameter, determining whether the parameter type corresponding to the initial state parameter satisfies a processing condition or not, so as to obtain a first determination result; and
when the first determination result indicates that the parameter type corresponding to the initial state parameter satisfies the processing condition, obtaining a state parameter of the sintering device corresponding to the initial state parameter according to the initial state parameter and a preset data processing rule.

In the embodiment of the present disclosure, for any initial state parameter, the parameter type corresponding to the initial state parameter information is determined.

Alternatively, the parameter type includes a digital type, and/or an analog type, which is not limited in the embodiment of the present disclosure.

Alternatively, for any initial state parameter, a specific mode for determining whether the parameter type corresponding to the initial state parameter satisfies a processing condition or not, so as to obtain a first determination result is as follows:
for any initial state parameter, determining whether the parameter type corresponding to the initial state parameter information is an analog type.

When the parameter type corresponding to the initial state parameter is the analog type, the first determination result is that the parameter type corresponding to the initial state parameter satisfies the processing condition.

When the parameter type corresponding to the initial state parameter is not the analog type, the first determination result is that the parameter type corresponding to the initial state parameter does not satisfy the processing condition.

Alternatively, when the first determination result indicates that the parameter type corresponding to the initial state parameter satisfies the processing condition, a specific mode for obtaining the state parameter of the sintering device corresponding to the initial state parameter according to the initial state parameter and the preset data processing rule is as follows:
initially filtering the initial state parameter to obtain a first state parameter, and converting the first state parameter into a digital quantity state parameter, and filtering the digital quantity state parameter to obtain the state parameter of the sintering device corresponding to the initial state parameter.

Alternatively, when the first determination result indicates that the parameter type corresponding to the initial state parameter does not satisfy the processing condition, a specific mode for obtaining the state parameter of the sintering device corresponding to the initial state parameter according to the initial state parameter and the preset data processing rule is as follows:
filtering the initial state parameter to obtain the state parameter of the sintering device corresponding to the initial state parameter.

It can be seen that by implementing a method for evaluating a health state of a sintering device described by the embodiment of the present disclosure, a processing mode of the initial state parameter can be determined by determining whether the initial state parameter satisfies the processing condition or not, and then the state parameter of the sintering device is obtained according to a data processing rule, such that the rapid and accurate evaluation of the health state of the sintering device is facilitated, thereby improving the capability of fault prediction and intelligent operation and maintenance for the sintering device.

### Embodiment 3

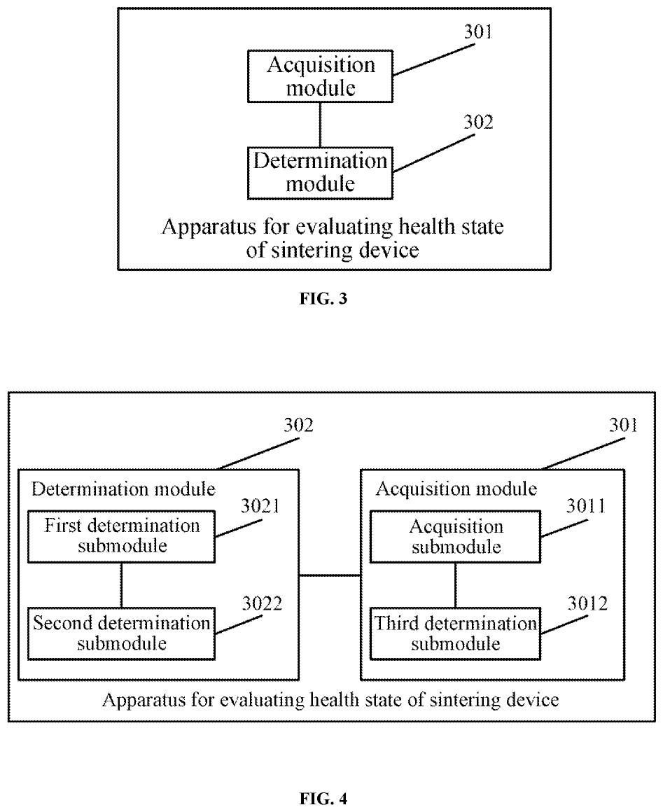

Please referring to FIG. 3, FIG. 3 is a structural diagram of an apparatus for evaluating a health state of a sintering device according to embodiments of the present disclosure. The apparatus described in FIG. 3 can be applied to a device health system, such as a local server or cloud server for evaluating and managing the health state of the sintering device, which is not limited in the embodiment of the present disclosure. As shown in FIG. 3, the apparatus includes:
an acquisition module 301, configured to acquire state information of a sintering device, where the state information of the sintering device includes at least one state parameter of the sintering device; and
a determination module 302, configured to determine a health state of the sintering device according to the state information of the sintering device and a preset health state evaluation rule, where the health state of the sintering device is used for indicating intelligent operation and maintenance for the sintering device.

It can be seen that by implementing the apparatus for evaluating a health state of a sintering device described in FIG. 3, the health state of the sintering device for indicating intelligent operation and maintenance for the sintering device can be determined by acquiring the state information of the sintering device and using the health state evaluation rule, such that the rapid and accurate evaluation of the health state of the sintering device is facilitated, thereby improving the capability of fault prediction and intelligent operation and maintenance for the sintering device.

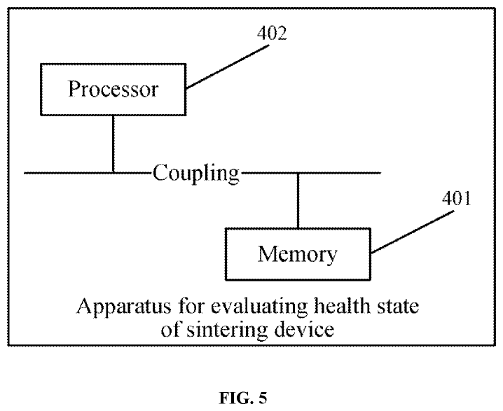

In another alternative embodiment, as shown in FIG. 4, the determination module 302 includes a first determination submodule 3021 and a second determination submodule 3022.

The first determination submodule 3021 is configured to determine a parameter health state set according to the state information of the sintering device, where the parameter health state set includes a deviation value corresponding to at least one state parameter of the sintering device.

The second determination submodule 3022 is configured to determine the health state of the sintering device according to the parameter health state set.

It can be seen that by implementing the apparatus for evaluating a health state of a sintering device described in FIG. 4, a parameter health state set including the deviation value corresponding to the state parameter of the sintering device can be determined according to the state information of the sintering device, and the health state of the sintering device can be determined. An implementation path for determining the health state of the sintering device is provided, such that the rapid and accurate evaluation of the health state of the sintering device is facilitated, thereby improving the capability of fault prediction and intelligent operation and maintenance for the sintering device.

In still another alternative embodiment, as shown in FIG. 4, a specific mode for the first determination submodule 3021 to determine a parameter health state set according to the state information of the sintering device is as follows:
for any state parameter of the sintering device, determining a deviation value corresponding to the state parameter of the sintering device according to the state parameter of the sintering device and a preset reference value corresponding to the state parameter of the sintering device.

It can be seen that by implementing an apparatus for evaluating a health state of a sintering device described in FIG. 4, a deviation value corresponding to the state parameter of the sintering device can be determined according to the state parameter of the sintering device and the reference value corresponding to the state parameter of the sintering device, such that the rapid and accurate evaluation of the health state of the sintering device is facilitated, thereby improving the capability of fault prediction and intelligent operation and maintenance for the sintering device.

In still another alternative embodiment, as shown in FIG. 4, a specific mode for the first determination submodule 3021 to determine a health state of the sintering device according to the parameter health state set is as follows:
determining a device parameter state type according to the parameter health state set;
determining whether the device parameter state type is matched with a fault type or not, so as to obtain a first matching result;
when the first matching result indicates that the device parameter state type is matched with the fault type, determining the health state of the sintering device according to the device parameter state type;
when the first matching result indicates that the device parameter state type is mismatched with the fault type, determining a parameter deviation set according to the state information of the sintering device, where the parameter deviation set includes a deviation change rate corresponding to at least one state parameter of the sintering device; and
determining the health state of the sintering device according to the parameter health state set.

It can be seen that by implementing the apparatus for evaluating a health state of a sintering device described in FIG. 4, the health state of the sintering device can be determined by determining the device parameter state type, and then the parameter deviation set including the deviation change rate corresponding to the state parameter of the sintering device is determined according to the state information of the sintering device, and then the health state of the sintering device is determined according to the parameter health state set and the parameter deviation set, such that the rapid and accurate evaluation of the health state of the sintering device is facilitated, thereby improving the capability of fault prediction and intelligent operation and maintenance for the sintering device.

In still another alternative embodiment, as shown in FIG. 4, the device parameter state type includes a device parameter fault type, and/or a device parameter health type.

A specific mode for the second determination submodule 3022 to determine the device parameter type state according to the parameter health state set is as follows:
determining a parameter state type set according to the parameter health state set, where the parameter state type set includes a parameter state type corresponding to at least one state parameter of the sintering device;
matching all parameter state types in the parameter state type set with the parameter fault type to obtain a second matching result;
when the second matching result indicates that there is a target parameter state type matched with the parameter fault type in the parameter state type set, determining the device parameter state type as the device parameter fault type; and
when the second matching result indicates that there is no target parameter state type matched with the parameter fault type in the parameter state type set, determining the device parameter state type as the device parameter health type.

It can be seen that by implementing an apparatus for evaluating a health state of a sintering device described in FIG. 4, the parameter state type set can be determined according to the parameter health state set, and then the device parameter state type is determined by matching, such that the rapid and accurate evaluation of the health state of the sintering device is facilitated, thereby improving the capability of fault prediction and intelligent operation and maintenance for the sintering device.

In still another alternative embodiment, as shown in FIG. 4, a specific mode for the second determination submodule 3022 to determine a health state of the sintering device according to the parameter health state set and the parameter deviation set is specifically as follows:
determining a parameter health value set according to the parameter health state set and the parameter deviation set, where the parameter health value set includes a parameter health value corresponding to at least one state parameter of the sintering device; and
determining the health state of the sintering device according to the parameter health value set and a preset weighted evaluation rule.

It can be seen that by implementing the apparatus for evaluating a health state of a sintering device described in FIG. 4, the parameter health value set can be determined according to the parameter health state set and the parameter deviation set, and the health state of the sintering device can be determined according to the weighted evaluation rule, such that the rapid and accurate evaluation of the health state of the sintering device is facilitated, thereby improving the capability of fault prediction and intelligent operation and maintenance for the sintering device.

In still another alternative embodiment, as shown in FIG. 4, the acquisition module 301 includes an acquisition submodule 3011, and a third determination submodule 3012.

The acquisition submodule 3011 is configured to acquire initial state parameter information 3011, where the initial state parameter information includes at least one initial state parameter.

The third determination submodule 3012 is configured to determine state information of the sintering device according to the initial state parameter information.

It can be seen that by implementing an apparatus for evaluating a health state of a sintering device described in FIG. 4, the state information of the sintering device can be determined through the initial state parameter information, and then the health state of the sintering device for indicating intelligent operation and maintenance for the sintering device can be determined by using a health state evaluation rule, such that the rapid and accurate evaluation of the health state of the sintering device is facilitated, thereby improving the capability of fault prediction and intelligent operation and maintenance for the sintering device.

In still another alternative embodiment, as shown in FIG. 4, a specific mode for the third determination submodule 3012 to determine a health state of the sintering device according to the initial state parameter information is as follows:
determining an initial state parameter type set according to the initial state parameter information, where the initial state parameter type set includes a parameter type corresponding to at least one initial state parameter;
for any initial state parameter, determining whether the parameter type corresponding to the initial state parameter satisfies a processing condition or not, so as to obtain a first determination result; and
when the first determination result indicates that the parameter type corresponding to the initial state parameter satisfies the processing condition, obtaining a state parameter of the sintering device corresponding to the initial state parameter according to the initial state parameter and a preset data processing rule.

It can be seen that by implementing the apparatus for evaluating a health state of a sintering device described in FIG. 4, a processing mode of the initial state parameter can be determined by determining whether the initial state parameter satisfies the processing condition or not, and then the state parameter of the sintering device is obtained according to a data processing rule, such that the rapid and accurate evaluation of the health state of the sintering device is facilitated, thereby improving the capability of fault prediction and intelligent operation and maintenance for the sintering device.

### Embodiment 4

Please referring to FIG. 5, FIG. 5 is a structural diagram of still another apparatus for evaluating a health state of a sintering device according to embodiments of the present disclosure. The apparatus described in FIG. 5 can applied to a device health system, such as a local server or cloud server for evaluating and managing the health state of the sintering device, which is not limited in the embodiment of the present disclosure. As shown in FIG. 5, the apparatus includes:
a memory 401 in which executable program codes are stored; and
a processor 402, coupled to the memory 401.

The processor 402 calls the executable program codes stored in the memory 401 to execute a part or all of steps in the method for evaluating a health state of a sintering device described in Embodiment 1 or Embodiment 2.

### Embodiment 5

The embodiment of the present disclosure discloses a computer readable storage medium for storing computer program for electronic data exchange. The computer program enables a computer to execute steps in the method for evaluating a health state of a sintering device described in Embodiment 1 or Embodiment 2.

### Embodiment 6

The embodiment of the present disclosure discloses a computer program product, including a non-transitory computer-readable storage medium in which computer program is stored, and the computer program is operable to enable a computer to execute the steps in method for evaluating a health state of a sintering device described in Embodiment 1 or Embodiment 2.

The device embodiments described above are only schematic, in which the modules described as separate components may or may not be physically separated, and the components displayed as modules may or may not be physical modules, that is, they may be located in one place, or may be distributed to multiple network modules. A part or all of the modules can be selected according to actual needs to achieve the purpose of this embodiment. Those of ordinary skill in the art can understand and implement the embodiment without creative labor.

Through the specific description of the above embodiments, those skilled in the art can clearly understand that the various embodiments can be implemented by software and a necessary universal hardware platform. Of course, the embodiments may also be implemented by hardware. Based on such an understanding, the above technical solutions substantially or the portions contributing to the related art may be embodied in the form of a software product. The computer software product may be stored in a computer-readable storage medium. The computer-readable storage medium includes a read-only memory (ROM), a random-access memory (RAM), a programmable read-only memory (PROM), an erasable programmable read-only memory (EPROM), a one-time programmable read-only memory (OTPROM), an electrically-erasable programmable read-only memory (EEPROM), a compact disc read-only memory (CD-ROM) or other optical disk memories, disc memories, magnetic tape memories, or any other computer readable media capable of carrying or storing data.

Finally, the method and apparatus for evaluating the health state of the sintering device disclosed in the embodiment of the present disclosure disclose only a preferred embodiment of the present disclosure, which are only used to illustrate the technical solution of the present disclosure rather than limiting. Although the present disclosure has been described in detail with reference to the foregoing embodiments, those of ordinary skill in the art should understand that it is still possible to modify the technical solution described in the foregoing embodiments, or to replace some technical features with equivalents. However, these modifications or substitutions do not make the essence of the corresponding technical solutions deviate from the spirit and scope of the technical solutions of various embodiments of the present disclosure.

1. A method for evaluating a health state of a sintering device, comprising the following steps:
acquiring state information of a sintering device, wherein the state information of the sintering device comprises at least one state parameter of the sintering device; and
determining a health state of the sintering device according to the state information of the sintering device and a preset health state evaluation rule, wherein the health state of the sintering device is used for indicating intelligent operation and maintenance for the sintering device.

2. The method for evaluating a health state of a sintering device according to claim 1, wherein determining a health state of the sintering device according to the state information of the sintering device and a preset health state evaluation rule comprises the following steps:
determining a parameter health state set according to the state information of the sintering device, wherein the parameter health state set comprises a deviation value corresponding to at least one state parameter of the sintering device; and
determining the health state of the sintering device according to the parameter health state set.

3. The method for evaluating a health state of a sintering device according to claim 2, wherein determining a parameter health state set according to the state information of the sintering device comprises the following steps:
for any state parameter of the sintering device, determining a deviation value corresponding to the state parameter of the sintering device according to the state parameter of the sintering device and a preset reference value corresponding to the state parameter of the sintering device.

4. The method for evaluating a health state of a sintering device according to claim 3, wherein determining a health state of the sintering device according to the parameter health state set comprises the following steps:
determining a device parameter state type according to the parameter health state set;
determining whether the device parameter state type is matched with a fault type to obtain a first matching result;
when the first matching result indicates that the device parameter state type is matched with the fault type, determining the health state of the sintering device according to the device parameter state type;
when the first matching result indicates that the device parameter state type is mismatched with the fault type, determining a parameter deviation set according to the state information of the sintering device, wherein the parameter deviation set comprises a deviation change rate corresponding to at least one state parameter of the sintering device; and
determining the health state of the sintering device according to the parameter health state set and the parameter deviation set.

5. The method for evaluating a health state of a sintering device according to claim 4, wherein the device parameter state type comprises a device parameter fault type, and/or a device parameter health type;
determining the device parameter state type according to the parameter health state set comprises the following steps:
determining a parameter state type set according to the parameter health state set, wherein the parameter state type set comprises a parameter state type corresponding to at least one state parameter of the sintering device;
matching all parameter state types in the parameter state type set with the parameter fault type to obtain a second matching result;
when the second matching result indicates that a target parameter state type matched with the parameter fault type exists in the parameter state type set, determining the device parameter state type as the device parameter fault type; and
when the second matching result indicates no target parameter state type matched with the parameter fault type exists in the parameter state type set, determining the device parameter state type as the device parameter health type.

6. The method for evaluating a health state of a sintering device according to claim 4, wherein determining a health state of the sintering device according to the parameter health state set and the parameter deviation set comprises the following steps:
determining a parameter health value set according to the parameter health state set and the parameter deviation set, wherein the parameter health value set comprises a parameter health value corresponding to at least one state parameter of the sintering device; and
determining the health state of the sintering device according to the parameter health value set and a preset weighted evaluation rule.

7. The method for evaluating a health state of a sintering device according to claim 1, wherein acquiring state information of the sintering device comprises the following steps:
acquiring initial state parameter information, wherein the initial state parameter information comprises at least one initial state parameter; and
determining state information of the sintering device according to the initial state parameter information.

8. The method for evaluating a health state of a sintering device according to claim 7, wherein determining state information of the sintering device according to the initial state parameter information comprises the following steps:
determining an initial state parameter type set according to the initial state parameter information, wherein the initial state parameter type set comprises a parameter type corresponding to at least one initial state parameter;
for any initial state parameter, determining whether the parameter type corresponding to the initial state parameter satisfies a processing condition or not, so as to obtain a first determination result; and
when the first determination result indicates that the parameter type corresponding to the initial state parameter satisfies the processing condition, obtaining a state parameter of the sintering device corresponding to the initial state parameter according to the initial state parameter and a preset data processing rule.

9. An apparatus for evaluating a health state of a sintering device, comprising:
an acquisition module, configured to acquire state information of a sintering device, wherein the state information of the sintering device comprises at least one state parameter of the sintering device; and
a determination module, configured to determine a health state of the sintering device according to the state information of the sintering device and a preset health state evaluation rule; wherein the health state of the sintering device is used for indicating intelligent operation and maintenance for the sintering device.

10. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 1.

11. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 2.

12. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 3.

13. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 4.

14. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 5.

15. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 6.

16. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 7.

17. An apparatus for evaluating a health state of a sintering device, comprising:
a memory, in which executable program codes are stored; and
a processor coupled to the memory;
wherein the processor calls the executable program codes stored in the memory to execute the method for evaluating a health state of a sintering device according to claim 8.
